(19) United States
(12) Patent Application Publication
(10) Pub. No.: US 2024/0404883 A1
(43) Pub. Date: Dec. 5, 2024

(54) SILICON CARBIDE CHIP, SEMICONDUCTOR DEVICE AND METHOD FOR MANUFACTURING A SILICON CARBIDE CHIP

(71) Applicant: Infineon Technologies AG, Neubiberg (DE)

(72) Inventors: Franz-Josef Pichler, Villach (AT); Fong Lim, Air Keroh (MY); Marko Omazic, Villach (AT); Wee Khim Teng, Batu Berendam (MY); Adbul Rahman Mohamed, Muar (MY)

(21) Appl. No.: 18/672,204

(22) Filed: May 23, 2024

(30) Foreign Application Priority Data
Jun. 1, 2023 (MY) MYPI2023003278
Jan. 19, 2024 (DE) 102024101618.3

(51) Int. Cl. H01L 21/78; H01L 23/00; H01L 23/495

(52) U.S. Cl. CPC H01L 21/78; H01L 23/49513; H01L 24/05; H01L 24/29; H01L 24/32; H01L 2224/05611; H01L 2224/05638; H01L 2224/05644; H01L 2224/05647; H01L 2224/05655; H01L 2224/29111; H01L 2224/29144; H01L 2224/29147; H01L 2224/29155; H01L 2224/32245; H01L 2924/01014; H01L 2924/0132; H01L 2924/014; H01L 2924/10156; H01L 2924/10272; H01L 2924/3512

(57) ABSTRACT

A silicon carbide chip includes a first main surface, a second main surface, and a side face. An angle α between the side face and a horizontal plane measured in the silicon carbide material is more than 78°, the angle α being measured in a region adjacent to the second main surface. Also described is a method for manufacturing the silicon carbide chip.

### BACKGROUND

During the manufacture of semiconductor devices, the single components are usually processed on a wafer scale. Thereafter, the wafers are singulated into single semiconductor chips. Generally, methods are being sought, by which the dicing process may be improved, resulting in more reliable semiconductor chips.

### SUMMARY

It is an object of the present invention to provide an improved semiconductor chip and an improved method for forming a semiconductor chip.

According to embodiments, a silicon carbide chip comprises a first main surface, a second main surface, and a side face, wherein an angle α between the side face and a horizontal plane measured in the silicon carbide material is more than 78°, the angle α being measured in a region adjacent to the second main surface.

According to further embodiments, a silicon carbide chip comprises a first main surface, a second main surface, a side face, and a layer of an intermetallic compound adjacent to the side face. The layer of the intermetallic compound has a thickness of less than 2 μm in a region at a distance of less than 20 μm to the second main surface, the thickness being measured in a direction parallel to the first main surface.

According to further embodiments, a silicon carbide chip comprises a first main surface, a second main surface, and a side face. A radius of curvature of an intersection between the second main surface and the side face is more than 0.5 μm.

A semiconductor device may comprise the silicon carbide chip as described above, a lead frame, and a solder material. The second main surface of the silicon carbide chip is arranged adjacent to the lead frame and is connected to the lead frame using the solder material.

According to embodiments, a method for manufacturing a silicon carbide chip may comprise defining a dicing kerf in a first main surface of a workpiece, and increasing a depth of the dicing kerf to obtain an opening. The method may additionally comprise further increasing the depth of the opening to a position less than 20% of a thickness of the workpiece relative to a second main surface of the workpiece, performing an annealing process to increase a width of the dicing kerf, and further increasing the depth of the opening to singulate the workpiece into silicon carbide chips.

### BRIEF DESCRIPTION OF THE FIGURES

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIGS. 1A to 1D illustrate cross-sectional views of a silicon carbide chip and of a semiconductor device comprising a silicon carbide chip.

FIG. 2 is an illustrative drawing for explaining effects according to embodiments.

FIGS. 3A to 3E are cross-sectional views of a workpiece when performing a method according to embodiments.

FIG. 4 summarizes a method according to embodiments.

### DETAILED DESCRIPTION

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “over”, “on”, “above”, “leading”, “trailing” etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

The terms “wafer”, “substrate” or “semiconductor substrate” used in the following description may include any semiconductor-based structure that has a semiconductor surface. Wafer and structure may be understood to include silicon, silicon-on-insulator (SOI), silicon-on sapphire (SOS), doped and undoped semiconductors, epitaxial layers of silicon supported by a base semiconductor foundation, and other semiconductor structures. Within the present disclosure the above terms may specifically refer to silicon carbide (SiC).

The terms “lateral” and “horizontal” as used in this specification may describe an orientation parallel or essentially parallel (i.e., deviating by at most ±5°) to a first surface of a substrate or semiconductor body. This can be for instance the surface of a wafer or a die.

The term “vertical” as used in this specification may describe an orientation which is arranged perpendicular to the first surface of a substrate or semiconductor body.

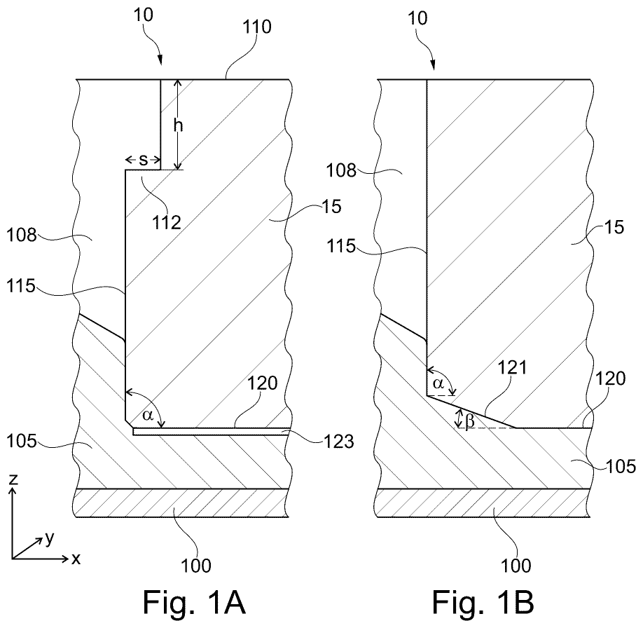

FIG. 1A shows a silicon carbide chip 15 according to embodiments. The silicon carbide chip 15 comprises a first main surface 110, a second main surface 120 and a side face 115. Semiconductor components, such as transistors, diodes and others (not shown) may be arranged in the silicon carbide chip 15. For example, the semiconductor components may be arranged in a region neighbouring the first main surface 110.

Generally, a size of the silicon carbide chip 15 may be approximately 8 mm², e.g. less than (3 mm*3 mm). However, chip sizes below 1 mm² or above 8 mm² may also be possible. A total thickness of the silicon carbide substrate may be larger than 50 μm or larger than 80 μm or larger than 100 μm. A thickness of the silicon carbide chip 15 may be less than 250 μm or less than 200 μm or less than 150 μm or less than 130 μm.

According to embodiments, the silicon carbide chip 15 may be mounted to a lead frame 100, thus forming a semiconductor device 10. In this case, the second main surface 120 may be arranged on a side facing the lead frame 100. For example, a solder material 105 that may e.g. comprise a suitable alloy, e.g. an AuSn alloy, an CuSn alloy, or a NiSn alloy may be used for electrically and physically connecting the silicon carbide chip 15 to the lead frame 100. Further, a molding material 108 may be used for packaging the silicon carbide chip 15.

As is illustrated in FIG. 1A, an angle α between the side face 115 and a horizontal direction measured in the silicon carbide material may be more than 78°. According to further embodiments, the angle α may be more than 80° or more than 84°. The angle α is measured in a region adjacent to the second main surface 120. Accordingly, in a region adjacent to the second main surface 120, the side face 115 may extend at an angle α against a horizontal plane, e.g. the x-y plane. The side face 115 does not need to be a straight line or flat plane. According to implementations, the side face 115 may be slightly curved, and the angle α may be measured between a tangent to the side face 115 and the horizontal plane. According to further implementations, a portion of the side face 115 neighbouring the second main surface 120 may be a straight line and the angle α is measured between this portion of the side face 115 and a horizontal plane. For example, this portion of the side face 115 may be at a distance of less than 30 μm from the second main surface 120.

For example, the angle α may be measured between the side face 115 and the second main surface 120. According to further embodiments, as is shown in FIG. 1B, the second main surface 120 may comprise an inclined portion 121 that may be adjacent to the side face 115. An angle θ between the inclined portion 121 and the horizontal plane may be more than 5°. The angle θ is measured outside the silicon carbide material. As can be taken from a comparison of FIGS. 1A and 1B, the angle α is measured inside the silicon carbide material, whereas the angle θ is measured outside the silicon carbide material. The angle θ may be smaller than 30°.

When the second main surface 120 comprises an inclined portion 121 as illustrated in FIG. 1B, the total angle between the side face 115 and the inclined portion 121 of the second main surface may be equal to α+β. For example, (α+β) may be larger than 90°, e.g. smaller than 150°.

When β=0°, i.e. the second main surface 120 does not comprise an inclined portion 121, the angle between the second main surface 120 and the side face 115 may be larger than 78° or larger than 80° or larger than 84°. For example, the angle between the second main surface 120 and the side face may be less than 102° or less than 100° or less than 94°.

As is further shown in FIG. 1A, according to embodiments, the side face 115 may comprise a step portion 112. The step portion 112 may be or may comprise a horizontal portion which extends towards inner portions of the silicon carbide chip 15. The step portion is arranged on a side facing the first main surface 110. For example, a lateral width s of the step portion may be more than approximately 5 μm. The lateral width of the step portion may be less than 30 μm or less than 20 μm. The lateral width s of the step portion 112 may correspond to a distance of a lower portion of the side face 115 close to the second main surface 120 (e.g. with a distance of at most 30 μm to the second main surface) and an upper portion of the side face adjacent to the first main surface 110. Moreover, a vertical distance h of the step portion 112 to the first main surface 110 may be less than approximately 20 μm. The vertical distance h may be more than 1 μm or more than 2 μm or more than 5 μm.

The silicon carbide chip 15 may further comprise a back side metallization layer 123. For example, the back side metallization layer 123 may comprise a suitable alloy. For example, the back side metallization layer 123 may comprise AuSn, CuSn or NiSn. Furthermore, the silicon carbide chip 15 may comprise a front side metallization layer (not shown in the Figures).

According to embodiments that are illustrated in FIG. 1C, a radius r of curvature of an intersection between the second main surface 120 and the side face 115 may be more than 0.5 μm, or more than 0.8 μm or more than 1.0 μm. In more detail, FIG. 1C shows a tangent circle 122 which is drawn about a point A so as to be a tangent to both the second main surface 120 and the side face 115. The tangent circle 122 may have a radius r of more than 0.5 μm, or more than 0.8 μm or more than 1.0 μm. Further elements of the silicon carbide chip 15 illustrated in FIG. 1C may be similar to or identical with those illustrated with reference to FIGS. 1A and 1B.

According to still further embodiments, as shown in FIG. 1D, an intermetallic compound 109 may be formed adjacent to the side face 115 of the silicon carbide chip 15. For example, the silicon carbide chip 15 may be singulated from a wafer using a laser dicing method, for example, dicing using a multi-beam laser. During this dicing process, due to the large amount of energy induced in the silicon carbide chip 15, an intermetallic compound 109 may be generated from a back side metallization layer 123. The intermetallic compound 109 may be deposited over the side face 115 of the silicon carbide chip 15. As is illustrated in FIG. 1D, for example, a thickness t of the intermetallic compound 109 may be measured in a horizontal direction, e.g. in a direction parallel to the x-y plane. A thickness t of the intermetallic compound 109 may be less than 2 μm (or less than 1.5 μm or less than 1 μm) in a distance d of less than 20 μm (or in a distance of less than 30 μm) from the second main surface 120. For example, the intermetallic compound may comprise a component of a backside metallization 123 of the silicon carbide chip 15 (shown in FIGS. 1A and 1C)). For example, the intermetallic compound may comprise any of Sn, Au, Cu, Si, O, C, Ni.

As is to be clearly understood, the elements described above with reference to FIGS. 1A, 1B, 1C, and 1D may be arbitrarily combined.

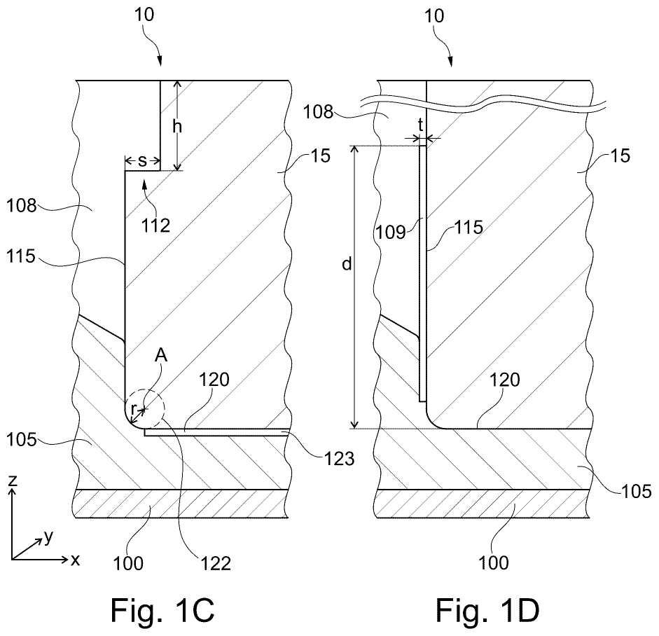

FIG. 2 illustrates stress which may be present, when a silicon carbide chip 15 is attached to a lead frame 100 via a solder material 105. For example, the lead frame 100 may comprise copper. The solder material 105 may comprise a suitable alloy, e.g. AuSn, CuSn or NiSn. When the silicon carbide chip is attached to the lead frame 100, the solder material 105 may squeeze out. As a consequence, there may be concentrated stress 23 in the small contact area between the solder squeeze-out and the side face 115. Moreover, thermo-mechanical stress 21 may be caused by interaction between the lead frame 100, solder squeeze-out and the condition of the side face 115. Still further, there may be induced tensile stresses 22 inside the silicon carbide chip 15. Due to the specific shape of the sidewall 115 as has been discussed above with reference to FIGS. 1A to 1D, e.g. the angle of the sidewall or the rounded corner having the specified radius of curvature, these stresses may be reduced. As a result, cracking and destruction of the silicon carbide chip 15 may be reduced.

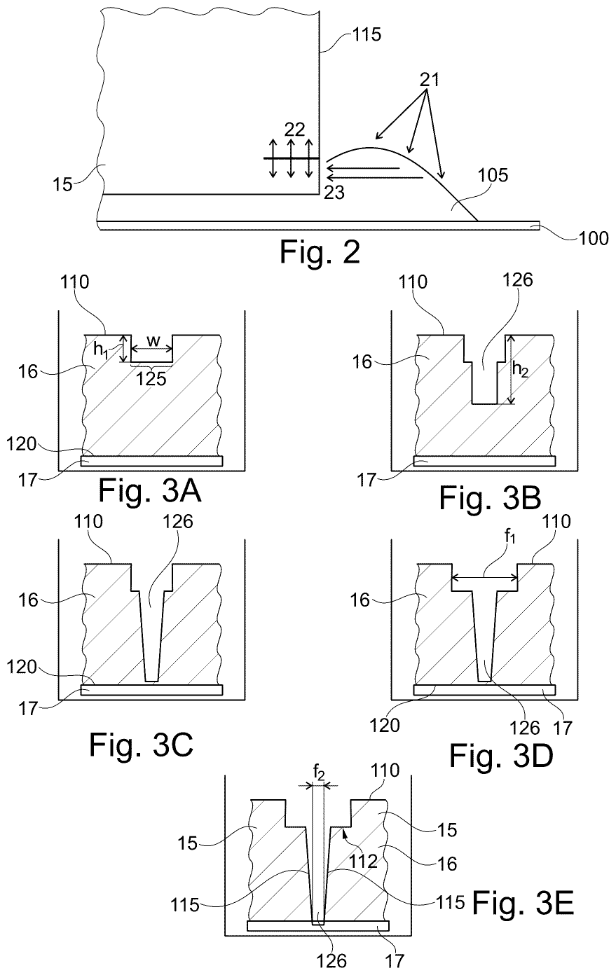

In the following, a method of manufacturing a single carbide chip 15 comprising singulating a workpiece 16 into single silicon carbide chips 15 will be explained while referring to FIGS. 3A to 3E.

The method may comprise a laser dicing process using a multi-beam laser (MBL). According to MBL methods a single laser beam may be shaped using a diffractive optical element (“DOE”) into a plurality of partial beams having a certain diameter and a certain distance. For example, the diffractive optical element may determine the shape of the intended intensity pattern. By adjusting the distance between the partial beams, the fluence, i.e. the energy per area, may be determined.

FIG. 3A shows a workpiece 16 which may correspond to or comprise two adjacent silicon carbide chips 15 having a first main surface 110 and a second main surface 120. A dicing kerf 125 is defined in the first main surface 110. For example, the dicing kerf 125 may be defined using a first MBL process using a first intensity pattern. A width w of the dicing kerf 125 may be larger than 8 μm or larger than 10 μm. The width w is measured in a horizontal direction. A depth h1 of the dicing kerf 125 may be larger than 10 μm, e.g. larger than 13 μm. Thereafter, as is shown in FIG. 3B, a depth of the dicing kerf 125 may be locally extended to define an opening 126. For example, the depth h2 may be more than 0.5*thickness of the workpiece measured in a vertical direction.

Thereafter, referring to FIG. 3C, the fluence of the partial beams of the dicing laser is largely increased. As a consequence, a depth of the opening 126 is further extended to a depth shortly before the second main surface 120 of the workpiece 16. For example, afterwards, the opening may be distanced to the second main surface by less than 20% (or less than 15% or less than 10%) of the thickness of the silicon carbide substrate. The opening may be distanced to the second main surface by more than 2% (or more than 3% or more than 5%) of the thickness of the silicon carbide substrate. For example, the opening may be distanced less than 15 μm or less than 10 μm, and more than 3 μm or even more than 5 μm, from the second main surface. Due to this extension of the opening 126, it may be possible that penetration to the second main surface 120 is not accomplished.

Thereafter, referring to FIG. 3D, an annealing process may be performed. Due to the annealing a heat-affected zone and a recast material may be removed. The annealing process may be performed at a larger width of the intensity pattern of the multi-beam irradiation. As a result, an upper width fᵢ of the dicing kerf 125 may be more than 25 μm, e.g. more than 30 μm.

Thereafter, a further laser process is performed at a small diameter f₂ of the intensity pattern to extend the opening 126 to the second main surface 120 of the workpiece 16. For example, f₂ may be less than 5 μm. For example, the shape of the laser beam for performing this laser process may be adjusted to form this intensity pattern. FIG. 3E shows an example of a resulting workpiece. As can be seen, the single silicon carbide chips 15 are separated.

The better controlled energy impact of the process described with reference to FIG. 3E to the second main surface 120 helps to form a rounded sidewall shape. Further, less intermetallic compound 109 may be formed on the side face 115 and/or the intermetallic compound 109 that is formed on the side face 115 may be more evenly distributed. A rounded shape is more robust against influence of the solder squeeze-out. As a consequence, chippings of substrate material may be avoided.

Since the form of the side face 115 and the interconnection between the side face 115 and the second main surface 120 are designed as has been described with reference to FIGS. 1A to 1D, the formation of the intermetallic compound 109 on the side face 115 may be influenced. As a result, the chip robustness may be significantly increased.

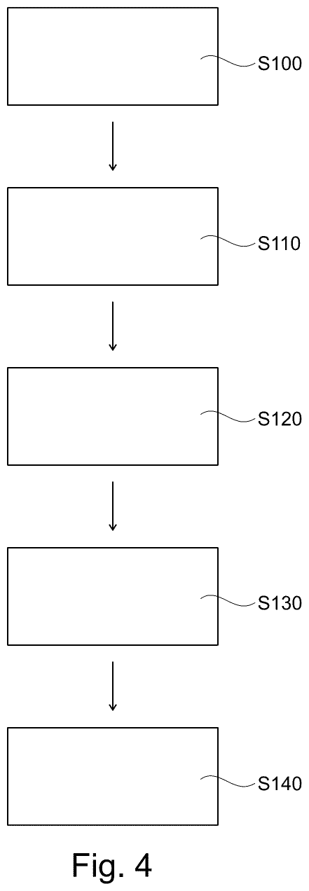

FIG. 4 summarizes a method according to embodiments. As is illustrated, a method for manufacturing a silicon carbide chip may comprises defining S100 a dicing kerf in a first main surface of a workpiece and increasing S110 a depth of the dicing kerf to obtain an opening. In addition, the method may comprise further increasing S120 the depth of the opening to a position less than 20% of a thickness of the workpiece relative to a second main surface of the workpiece, performing S130 an annealing process to increase a width of the dicing kerf and further increasing S140 the depth of the opening to singulate the workpiece into silicon carbide chips.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

What is claimed is:

1. A silicon carbide chip, comprising:
a first main surface;
a second main surface; and
a side face,
wherein an angle α between the side face and a horizontal plane measured in the silicon carbide material is more than 78°, the angle α being measured in a region adjacent to the second main surface.

2. The silicon carbide chip of claim 1, wherein the angle α is more than 80°.

3. The silicon carbide chip of claim 2, wherein the angle α is more than 84°.

4. The silicon carbide chip of claim 1, wherein the second main surface is horizontal.

5. The silicon carbide chip of claim 1, wherein the second main surface comprises an inclined portion adjacent to the side face, and wherein an angle β between the inclined portion and the horizontal plane is more than 5°, the angle β being measured outside the silicon carbide material.

6. The silicon carbide chip of claim 1, wherein the angle α is measured at a distance of less than 30 μm from the second main surface.

7. The silicon carbide chip of claim 1, wherein the silicon carbide chip is a laser-diced silicon carbide chip.

8. A semiconductor device, comprising:
the silicon carbide chip of claim 1;
a lead frame; and
a solder material,
wherein the second main surface of the silicon carbide chip is arranged adjacent to the lead frame and is connected to the lead frame using the solder material.

9. A silicon carbide chip, comprising:
a first main surface;
a second main surface;
a side face; and
a layer of an intermetallic compound adjacent to the side face,
wherein the layer of the intermetallic compound has a thickness of less than 2 μm in a region at a distance of less than 20 μm to the second main surface, the thickness being measured in a direction parallel to the first main surface.

10. A semiconductor device, comprising:
the silicon carbide chip of claim 9;
a lead frame; and
a solder material,
wherein the second main surface of the silicon carbide chip is arranged adjacent to the lead frame and is connected to the lead frame using the solder material.

11. A silicon carbide chip, comprising:
a first main surface;
a second main surface; and
a side face,
wherein a radius of curvature of an intersection between the second main surface and the side face is more than 0.5 μm.

12. The silicon carbide chip of claim 11, wherein the radius of curvature is more than 1.0 μm.

13. The silicon carbide chip of claim 11, further comprising a step portion at a distance h of less than 20 μm measured from the first main surface, the step portion extending to a lateral width s of at least 5 μm in a horizontal direction.

14. A semiconductor device, comprising:
the silicon carbide chip of claim 11,
a lead frame; and
a solder material;
wherein the second main surface of the silicon carbide chip is arranged adjacent to the lead frame and is connected to the lead frame using the solder material.

15. A method for manufacturing a silicon carbide chip, the method comprising:
defining a dicing kerf in a first main surface of a workpiece;
increasing a depth of the dicing kerf to obtain an opening;
further increasing the depth of the opening to a position less than 20% of a thickness of the workpiece relative to a second main surface of the workpiece;
performing an annealing process to increase a width of the dicing kerf; and
further increasing the depth of the opening to singulate the workpiece into silicon carbide chips.

16. The method of claim 15, wherein the method is performed using a multi-beam laser.
